(19) United States
(12) Patent Application Publication
(10) Pub. No.: US 2025/0008718 A1
(43) Pub. Date: Jan. 2, 2025

(54) COMPONENT MOUNTING MACHINE AND METHOD FOR CALCULATING CORRECTION VALUE

(71) Applicant: FUJI CORPORATION, Chiryu (JP)

(72) Inventor: Toshiaki MIZUNO, Toyota-shi (JP)

(73) Assignee: FUJI CORPORATION, Chiryu (JP)

(21) Appl. No.: 18/705,629

(22) PCT Filed: Nov. 24, 2021
(86) PCT No.: PCT/JP2021/043018

§ 371 Date: Apr. 29, 2024

(51) Int. Cl. H05K 13/08; H05K 13/04

(52) U.S. Cl. CPC H05K 13/089; H05K 13/0406; H05K 13/0409; H05K 13/0812; H05K 13/0815

(57) ABSTRACT

A component mounting machine includes a nozzle, a head, an XY movement mechanism, a board conveyance device, and a control device. A component mounting position setting section sets a component mounting position which is a position in an X direction and a Y direction at which a component is to be mounted. A component mounting height setting section sets a component mounting height which is a position in a Z direction at which the component is to be mounted. The mounting position correction section corrects the component mounting position of the component set by the component mounting position setting section with a first correction value that varies according to the component mounting height of the component set by the component mounting height setting section. The XY movement mechanism drive section drives the XY movement mechanism based on the component mounting position corrected by the mounting position correction section.

### TECHNICAL FIELD

The technique disclosed in the present description relates to a component mounting machine and a method for calculating a correction value for correcting a component mounting position of a nozzle of the component mounting machine.

### BACKGROUND ART

The component mounting machine of Patent Literature 1 measures an actual height in a Z direction for each board on which a component is mounted, and corrects the position in the Z direction where a nozzle is lifted and lowered based on the measured actual height.

### PATENT LITERATURE

Patent Literature 1: JP-A-2008-215904

### BRIEF SUMMARY

### Technical Problem

In the component mounting machine, for example, the nozzle may be lifted and lowered while being inclined with respect to the Z direction due to dimensional variations in components and during assembly. In this case, when the position in the Z direction (that is, the component mounting height) at which the nozzle is lifted and lowered changes, the positions in an X direction and a Y direction (that is, the component mounting positions) also change. Further, in the component mounting machine, the component mounting height may change according to the component to be mounted and the board. Therefore, when the component mounting height changes, the value of the positional deviation of the component mounting position may vary according to the component mounting height. Therefore, when the component mounting position is corrected, it is required to correct the component mounting position with different correction values according to the component mounting height. The technique of Patent Literature 1 can correct the component mounting height, which is a position in the Z direction, but does not correct the component mounting positions which are positions in the X direction and the Y direction according to the component mounting height. The present description provides a technique capable of mounting a component at a more accurate position by correcting a component mounting position with different correction values according to a component mounting height.

### Solution to Problem

A component mounting machine disclosed in the present description includes a nozzle, a head, an XY movement mechanism, a board conveyance device, and a control device. The nozzle picks up a component, and the nozzle is detachably attached to the head that includes a nozzle lifting and lowering mechanism configured to lift and lower the nozzle in a Z direction. The XY movement mechanism moves the head in an X direction and a Y direction. The board conveyance device carries a board into a board mounting position and carries the board out from the board mounting position. The control device controls the nozzle lifting and lowering mechanism, the XY movement mechanism, and the board conveyance device so that the component picked up by the nozzle is mounted on the board carried into the board mounting position. The control device includes a component mounting position setting section, a component mounting height setting section, a mounting position correction section, and an XY movement mechanism drive section. The component mounting position setting section sets, for each component to be mounted on the board, a component mounting position which is a position in the X direction and the Y direction at which the component is to be mounted. The component mounting height setting section sets, for each component to be mounted on the board, a component mounting height which is a position in the Z direction at which the component is to be mounted. The mounting position correction section corrects, for each component to be mounted on the board, the component mounting position of the component set by the component mounting position setting section with a first correction value that varies according to the component mounting height of the component set by the component mounting height setting section. The XY movement mechanism drive section drives the XY movement mechanism based on the component mounting position corrected by the mounting position correction section.

According to the configuration described above, the mounting position correction section corrects the component mounting position with the first correction value that varies according to the component mounting height of the component set by the component mounting height setting section. Accordingly, the component mounting position can be corrected with different correction values according to the component mounting height.

Further, the present description also discloses a method for calculating a correction value. The method for calculating a correction value in the present description includes a first mounting step, a first deviation acquisition step, a second mounting step, a second deviation acquisition step, and a correction value calculation step. In the first mounting step, a measurement component picked up by a nozzle is mounted at a component mounting target position which is a target position in an X direction and a Y direction set on a board mounting surface of a board positioned at a component mounting position of a component mounting machine in a state where a height of the board mounting surface is a first height. In the first deviation acquisition step, a first deviation is acquired, which is a deviation between an actual mounting position of the measurement component and the component mounting target position by performing the first mounting step multiple times. In the second mounting step, the measurement component picked up by the nozzle is mounted at the component mounting target position in a state where the height of the board mounting surface of the board positioned at the component mounting position of the component mounting machine is a second height different from the first height. In the second deviation acquisition step, a second deviation is acquired, which is a deviation between an actual mounting position of the measurement component and the component mounting target position by performing the second mounting step multiple times. In the correction value calculation step, a correction value for correcting the component mounting target position is calculated for each height of the board mounting surface of the board by using the first deviation and the second deviation.

According to the configuration described above, the correction value for correcting the component mounting target position can be calculated for each height of the board mounting surface of the board. Accordingly, the component mounting target position can be corrected with different correction values according to the board mounting height.

### BRIEF DESCRIPTION OF DRAWINGS

FIG. 1 is a schematic view of a component mounting machine according to an embodiment.

FIG. 2 is an enlarged view of a range surrounded by the broken line II in FIG. 1.

FIG. 3 shows a flowchart of processing executed by a control device.

FIG. 4 is a graph showing a relationship between a mounting height and a correction value.

FIG. 5 is an enlarged view similar to FIG. 2 in a first mounting step.

FIG. 6 is an enlarged view similar to FIG. 2 in a second mounting step.

### DESCRIPTION OF EMBODIMENTS

Component mounting machine 100 will be described with reference to drawings. Component mounting machine 100 includes component mounting unit 10, board conveyance device 30, control device 20, and part camera 26. Component mounting machine 100 is a device that mounts electronic component 2 (hereinafter, simply referred to as component 2) on multiple circuit boards 4 (hereinafter, simply referred to as boards 4).

Component mounting unit 10 includes nozzle 12, head 16, and XY movement mechanism 18. Nozzle 12 has a hollow shape. Nozzle 12 picks up component 2 to the lower end of nozzle 12 by making the space inside nozzle 12 a negative pressure by a compressor (not shown). When the space inside nozzle 12 has a positive pressure, picked-up component 2 is removed from the lower end of nozzle 12. In component mounting machine 100, multiple types of nozzles 12 are used. Each nozzle 12 is attachable to and detachable from head 16, and is exchanged according to the type of component 2.

XY movement mechanism 18 is a robot that moves head 16 in the X direction and the Y direction (that is, the horizontal direction). XY movement mechanism 18 includes a guide rail that guides head 16, an actuator that moves head 16 along the guide rail, and the like. That is, head 16 is attached to XY movement mechanism 18 to be movable in the horizontal direction.

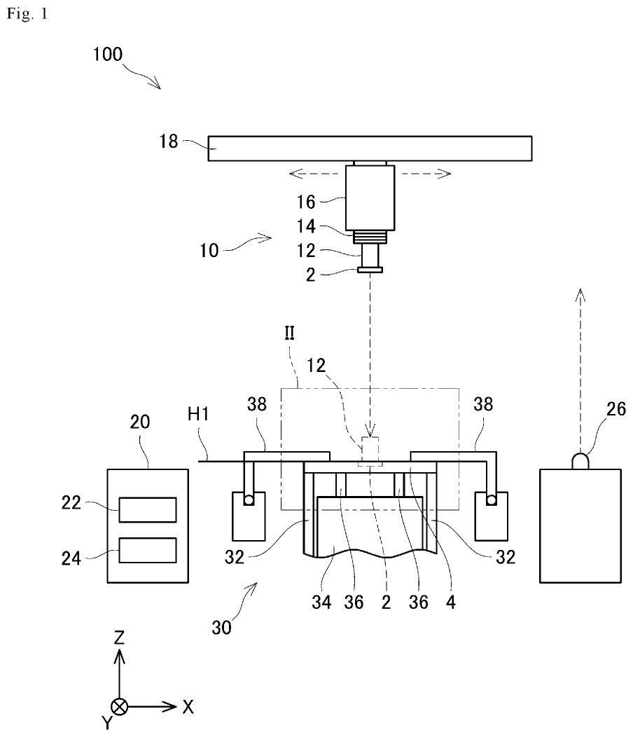

Head 16 includes nozzle lifting and lowering mechanism 14. Nozzle lifting and lowering mechanism 14 of head 16 can extend and contract in the Z direction (that is, the vertical direction of the paper surface in FIG. 1). When mounting component 2 on board 4, first, head 16 is moved onto a component feeder (not shown) by XY movement mechanism 18. Next, as nozzle lifting and lowering mechanism 14 extends in the Z direction, nozzle 12 is lowered, and component 2 is picked up to nozzle 12. Next, head 16 is moved above part camera 26 by XY movement mechanism 18, and part camera 26 images component 2 picked up by nozzle 12. When it is determined that component 2 is normally picked up by nozzle 12 based on the image captured by part camera 26, head 16 is moved to a predetermined position above board 4 by XY movement mechanism 18. Thereafter, when nozzle 12 is lowered to an appropriate height, component 2 is removed from the lower end of nozzle 12. Thus, as indicated by the broken line in FIG. 1, component 2 is mounted on the upper surface (that is, the board mounting surface) of board 4. Thereafter, as nozzle lifting and lowering mechanism 14 contracts in the Z direction, nozzle 12 is lifted.

Board conveyance device 30 includes belt conveyor 32, backup plate 34, support pins 36, and clamps 38. Board conveyance device 30 conveys board 4 in the Y direction (that is, the back direction of the paper surface in FIG. 1) by belt conveyor 32. With supported from below by belt conveyor 32, backup plate 34, and support pins 36, board 4 is fixed from above by clamps 38 from both sides in the X direction. Thus, board 4 is fixed to the board mounting position. After component 2 is mounted on board 4 fixed to the board mounting position, board conveyance device 30 carries out board 4 on which component 2 is mounted from the board mounting position by belt conveyor 32. Thereafter, new board 4 is disposed at the board mounting position again.

In this manner, board conveyance device 30 conveys multiple boards 4 to the board mounting position by repeatedly sending boards 4 in the Y direction, and component mounting unit 10 mounts component 2 on board 4 fixed to the board mounting position by clamps 38.

Control device 20 is a computer including CPU 22 and memory 24. CPU 22 controls component mounting machine 100 based on various programs stored in memory 24. Memory 24 stores reference height H1. Reference height H1 is a height at which board 4 having a standard thickness comes into contact with clamps 38. That is, reference height H1 is the height of the component mounting surface of board 4 having a standard thickness. Reference height H1 is a height serving as a reference for lifting and lowering nozzle 12. Reference height H1 is set, for example, when manufacturing component mounting machine 100.

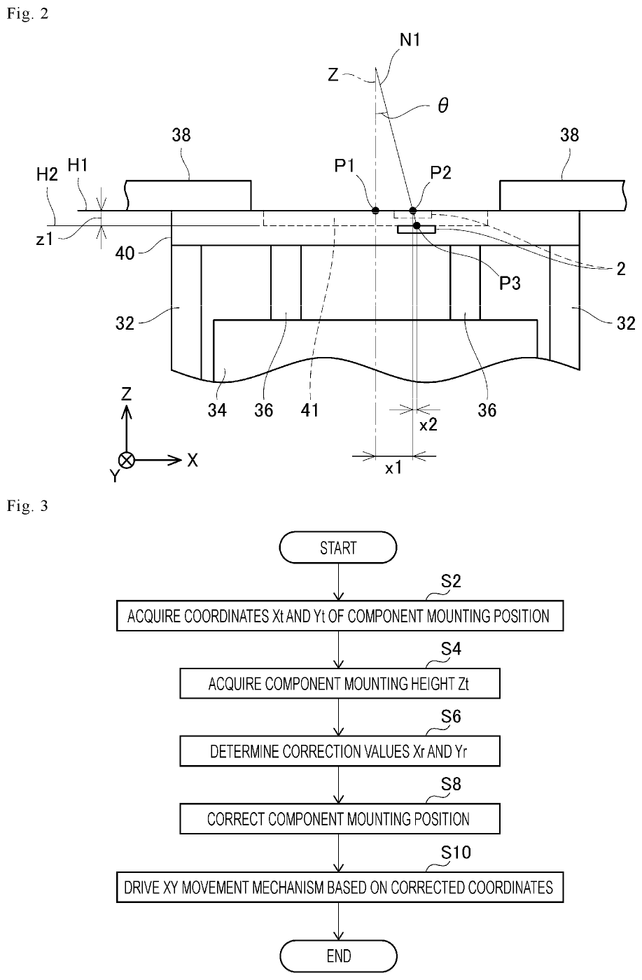

With reference to FIG. 2, the positional deviation in the X direction that occurs as nozzle 12 is lifted and lowered will be described. Nozzle 12 is designed to be lifted and lowered parallel to the Z direction (that is, the vertical direction). However, in practice, the direction in which nozzle 12 is lifted and lowered may be inclined with respect to the Z direction due to variations in dimensions of components of component mounting machine 100, variations during assembly, inclination of the ground surface on which component mounting machine 100 is disposed, and the like. In FIG. 2, the Z direction is indicated by an alternate long and short dash line, and the direction in which nozzle 12 is actually lifted and lowered is indicated by lifting and lowering direction N1. Lifting and lowering direction N1 is inclined by angle θ with respect to the Z direction. In FIG. 2, angle θ is enlarged for easy understanding.

When mounting component 2 at reference height H1 in component mounting machine 100 in which nozzle 12 is lifted and lowered in lifting and lowering direction N1, component 2 is mounted at mounting position P2 as illustrated in FIG. 2. As a result, mounting position P2 is deviated in the X direction by distance x1 with respect to position P1 when nozzle 12 is lifted and lowered in the Z direction.

Here, board 40 on which component 2 is to be mounted may include recessed portion 41. The bottom surface of recessed portion 41 is lower than the upper surface of board 40. That is, when mounting component 2 on the bottom surface of recessed portion 41 by using component mounting machine 100, the height (that is, the board mounting surface) at which component 2 is to be mounted is second height H2 that is lower than reference height H1 by distance z1 in the Z direction. In this case, component 2 is mounted at mounting position P3. As illustrated in FIG. 2, mounting position P3 is deviated in the X direction by distance x2 with respect to mounting position P2.

As described above, when nozzle 12 is lifted and lowered in lifting and lowering direction N1 inclined by angle θ with respect to the Z direction, the magnitude of the positional deviation in the X direction in which component 2 is to be mounted varies according to the height of component 2 to be mounted. In FIG. 2, the positional deviation in the X direction has been described, but the position in the Y direction (that is, the front and back direction of the paper surface in FIG. 2) can be similarly deviated.

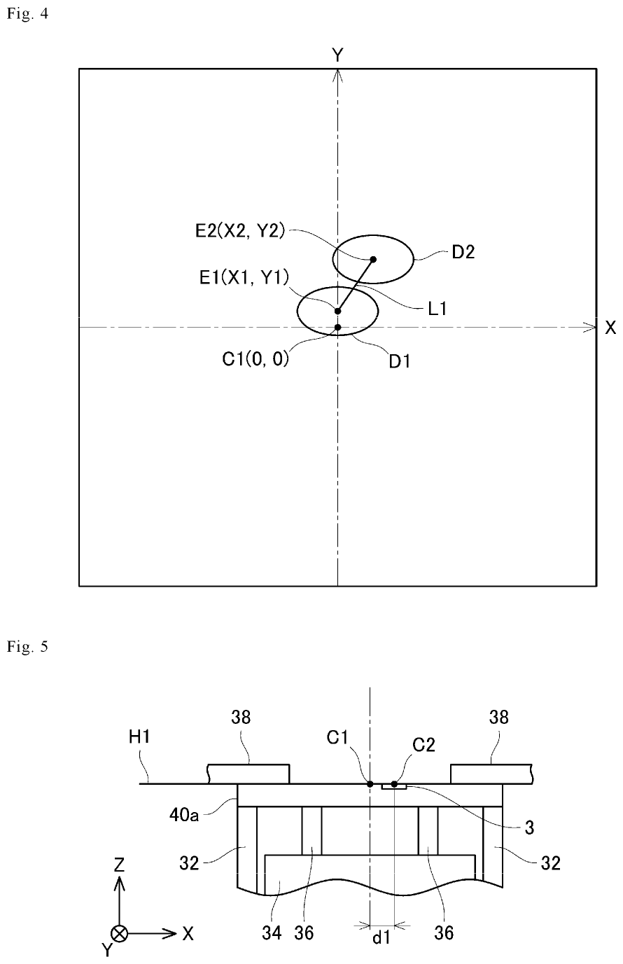

The processing executed by control device 20 of component mounting machine 100 will be described with reference to FIGS. 3 and 4. The processing of FIG. 3 is executed in a state where component 2 is picked up to the tip of nozzle 12 and board 4 is fixed to the board mounting position by clamp 38. The management device (not shown) has transmitted X-coordinate Xt and Y-coordinate Yt of the target position where component 2 is to be mounted to control device 20 in advance, and control device 20 stores each coordinate (Xt, Yt) of this target position in memory 24. Therefore, control device 20 acquires coordinates Xt and Yt of the target position of component 2 from memory 24, and sets acquired coordinates Xt and Yt as the component mounting position (S2).

Next, control device 20 sets mounting height Zt which is a height in the Z direction at which component 2 is to be mounted. Specifically, similarly to the target position (Xt, Yt) of component 2, the management device transmits the height of the mounting surface on which component 2 is to be mounted (that is, the distance in the Z direction from reference height H1 to the mounting height (mounting surface) (for example, distance z1 in FIG. 2)) to control device 20 in advance, and control device 20 stores transmitted mounting height Zt in memory 24. Control device 20 acquires mounting height Zt of component 2 from memory 24, and sets acquired mounting height Zt as a component mounting height (S4).

Further, control device 20 calculates correction values (Xr, Yr) for correcting the position of nozzle 12 based on the component mounting height (that is, mounting height Zt) set in S4 (S8). Specifically, control device 20 determines the correction value by applying mounting height Zt set in S4 to graph (function) L1 shown in FIG. 4.

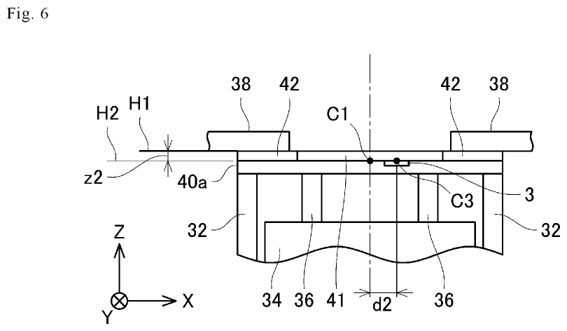

Control device 20 stores graph L1 of FIG. 4 in memory 24 in advance. Although details will be described later with reference to FIGS. 5 and 6, graph L1 is acquired by actually performing mounting multiple times by using component mounting machine 100. First mounting position group D1 is obtained by mounting components multiple times at reference height H1 (see FIG. 2) and plotting the positions of the mounted components. Second mounting position group D2 is obtained by mounting components multiple times at second height H2 (see FIG. 2) and plotting the positions of the mounted components. First center position E1 is a median value of each coordinate of first mounting position group D1. Similarly, second center position E2 is a median value of each coordinate of second mounting position group D2. Graph L1 is acquired by connecting center positions E1 and E2 with a straight line. That is, graph L1 is acquired by performing linear interpolation between center positions E1 and E2. Graph L1 (for example, a linear regression equation) may be calculated by performing other statistical processing (for example, regression analysis) on the results obtained multiple times.

Control device 20 determines correction value Xr in the X direction and correction value Yr in the Y direction by using mounting height Zt set in S4 and graph L1 (S6). Next, control device 20 corrects the coordinates (Xt, Yt) of the component mounting position set in S2 by using determined correction values Xr and Yr (S8). Specifically, control device 20 subtracts correction value Xr from X-coordinate Xt of the component mounting position and subtracts correction value Yr from Y-coordinate Yt of the component mounting position. Thereafter, control device 20 drives XY movement mechanism 18 based on the corrected component mounting position (that is, X-coordinate Xt−Xr and Y-coordinate Yt−Yr) (S10). Accordingly, head 16 is disposed at the corrected component mounting position.

Thereafter, control device 20 drives nozzle lifting and lowering mechanism 14 to move nozzle 12 down to component mounting height Zt. After mounting component 2, control device 20 moves nozzle 12, picks up new component 2, and repeats the processing of FIG. 3.

In this way, control device 20 corrects the position of nozzle 12 in the horizontal direction in consideration of the positional deviation of nozzle 12 in the horizontal direction which changes according to component mounting height Zt. As a result, in component mounting machine 100, for example, even when lifting and lowering direction N1 (see FIG. 1) of nozzle 12 is inclined with respect to the Z direction and the position of nozzle 12 in the horizontal direction changes according to the mounting height, component 2 can be accurately mounted on board 40.

A method for calculating graph L1 of FIG. 4 (that is, a method for calculating correction values Xr and Yr) will be described with reference to FIGS. 5 and 6. As illustrated in FIG. 5, in the first mounting step, measurement component 3 is mounted on board 40a multiple times in a state where the height at which board 40a and clamps 38 come into contact with each other is reference height H1. That is, measurement component 3 is mounted multiple times in a state where the height of the board mounting surface of board 40a positioned at the component mounting position by clamps 38 is reference height H1. At this time, the operator sets the component mounting position to component mounting target position C1 (hereinafter, simply referred to as target position C1) and mounts measurement component 3. As shown in FIG. 4, target position C1 is the origin in the horizontal direction.

In the first mounting step, control device 20 does not correct the horizontal position of nozzle 12. Control device 20 moves nozzle 12 that has picked up measurement component 3 to target position C1 by XY movement mechanism 18, and then moves nozzle 12 down to reference height H1. Thus, measurement component 3 is mounted on board 40a.

As a result, as shown in FIG. 5, measurement component 3 is mounted at first mounting position C2. At reference height H1, first deviation d1 is generated between target position C1 and first mounting position C2. In FIG. 5, first deviation d1 between target position C1 and first mounting position C2 in the X direction is described, but a deviation occurs similarly in the Y direction (that is, the front and back direction in FIG. 5). The operator plots first deviation d1. By performing this operation multiple times, first mounting position group D1 (see FIG. 4) is acquired.

Next, in the second mounting step, the operator places spacer 42 between board 40a and clamp 38. Accordingly, as illustrated in FIG. 6, the board mounting surface of board 40a has second height H2 lower than reference height H1 by distance 22 in the Z direction. In the second mounting step, measurement component 3 is mounted multiple times in a state where the height of the board mounting surface of board 40a is second height H2. Similarly to the first mounting step, in the second mounting step, the operator sets the component mounting position to target position C1 and mounts measurement component 3. As described with reference to FIG. 2, in particular, when lifting and lowering direction N1 of nozzle 12 is inclined with respect to the Z direction, the positional deviation in the horizontal direction in which nozzle 12 is lifted and lowered can change according to the height at which measurement component 3 is mounted. Therefore, as illustrated in FIG. 6, measurement component 3 is mounted at second mounting position C3. At second height H2, second deviation d2 is generated between target position C1 and second mounting position C3. The operator plots second deviation d2. By performing this operation multiple times, second mounting position group D2 (see FIG. 4) is acquired.

In this manner, mounting position groups D1 and D2 are acquired for each height of the board mounting surface. Graph L1 (see FIG. 4) is determined based on acquired mounting position groups D1 and D2. That is, in the calculation method described above, the correction value for correcting the position of nozzle 12 in the horizontal direction for each height of the board mounting surface is calculated by using first deviation d1 and second deviation d2. As described above, the positional deviation in the horizontal direction in which nozzle 12 is lowered occurs due to dimensional variations of the components of component mounting machine 100, variations during assembly, inclination of the ground surface on which component mounting machine 100 is to be disposed, and the like. Therefore, the positional deviation varies depending on each individual component mounting machine 100 even if component mounting machine 100 is designed in the same way. According to the calculation method described above, the correction value is calculated by plotting deviations d1 and d2 obtained by comparing target position C1 with actually mounted mounting positions C2 and C3. Accordingly, it is possible to calculate a correction value corresponding to each individual component mounting machine 100. As a result, the accuracy of mounting component 2 can be improved by correcting the component mounting position of component mounting machine 100 by using the correction value calculated as described above.

Further, measurement component 3 has the same dimensions as those of component 2 (see FIG. 1), and further has higher dimensional accuracy than mass-produced component 2. Measurement component 3 is made of, for example, ceramic. In the calculation method described above, deviations d1 and d2 between target position C1 and mounting positions C2 and C3 are measured by using measurement component 3 having a higher dimensional accuracy than mass-produced component 2. Accordingly, as compared with the method for measuring deviations d1 and d2 by using mass-produced component 2, it is possible to reduce the dimensional variation of the component itself to be mounted. As a result, deviations d1 and d2 measured in each mounting step do not include an error caused by the dimensional variation of the component itself. Accordingly, when deviations d1 and d2 are measured, the positional deviation of component mounting machine 100 can be more accurately measured.

(Correspondence relationship) Reference height H1 is an example of a “first height”. The processing of S2 is an example of processing executed by the “component mounting position setting section”. The processing of S4 is an example of processing executed by the “component mounting height setting section”. The processing of S8 is an example of processing executed by the “mounting position correction section”. The processing of S10 is an example of processing executed by the “XY movement mechanism drive section”. The acquisition of first mounting position group D1 by the operator plotting multiple first deviations d1 is an example of the “first deviation acquisition step”. The acquisition of second mounting position group D2 by the operator plotting multiple second deviations d2 is an example of the “second deviation acquisition step”.

As described above, although specific examples of the technique disclosed in the present description have been described in detail, these are mere examples and do not limit the scope of the claims. The technique described in the scope of claims includes various modifications and changes of the specific examples described above. Modification examples of the above embodiment are listed below.

(Modification Example 1) Control device 20 may capture an image of component 2 picked up by nozzle 12 by using part camera 26, and may further correct the horizontal position of nozzle 12 during component mounting by using the captured image. For example, when a component supplied from a component supply device is picked up by nozzle 12, the center of nozzle 12 may deviate from the center of the component. When the center of nozzle 12 is deviated from the center of the component, the component mounting position is deviated by the deviation. Control device 20 calculates the positional deviation between the center of nozzle 12 and the center of picked-up component 2 based on the captured image. In the processing of S8 of FIG. 3, control device 20 may further add a correction value corresponding to the calculated positional deviation of the center of component 2 with respect to the center of nozzle 12 to the correction values (Xr, Yr). In the present modification example, calculating the positional deviation of the center of component 2 with respect to the center of nozzle 12 by control device 20 is an example of processing executed by the “positional deviation calculation section”, and the correction value corresponding to the positional deviation of the center of component 2 is an example of the “second correction value”.

(Modification Example 2) When calculating the correction value, the operator need not mount measurement component 3 at reference height H1. In the modification example, measurement component 3 may be mounted at a position higher than reference height H1. In this case, for example, spacers may be disposed between board 40a and support pins 36. Accordingly, the board mounting surface of board 40a is higher than reference height H1. In this state, measurement component 3 may be mounted on the board mounting surface multiple times to measure the positional deviation of nozzle 12 in the horizontal direction on the board mounting surface higher than reference height H1. In the present modification example, the height of the board mounting surface higher than reference height H1 is an example of a “second height”.

(Modification Example 3) In the method for calculating the correction value disclosed in the present description, the positional deviation of nozzle 12 in the horizontal direction may be measured by mounting actually mass-produced component 2 on board 40a multiple times instead of measurement component 3.

Technical elements described in the present description, or the drawings exhibit technical usefulness alone or in various combinations, and are not limited to combinations described in claims as originally filed. In addition, the technique described in the present description, or the drawings simultaneously achieves multiple purposes, and has technical usefulness with achieving one purpose itself of the multiple purposes.

### REFERENCE SIGNS LIST

2: electronic component, 3: measurement component, 4, 40, 40a: circuit board, 10: component mounting unit, 12: nozzle, 14: nozzle lifting and lowering mechanism, 16: head, 18: XY movement mechanism, 20: control device, 22: CPU, 24: memory, 26: part camera, 30: board conveyance device, 32: belt conveyor, 34: backup plate, 36: support pin, 38: clamp, 41: recessed portion, 42: spacer, 100: component mounting machine, C1: component mounting target position, C2: first mounting position, C3: second mounting position, H1: reference height, H2: second height, d1: first deviation, d2: second deviation

1. A component mounting machine comprising:
a nozzle configured to pick up a component;
a head to which the nozzle is detachably attached, the head including a nozzle lifting and lowering mechanism configured to lift and lower the nozzle in a Z direction;
an XY movement mechanism configured to move the head in an X direction and a Y direction;
a board conveyance device configured to carry a board into a board mounting position and carry the board out from the board mounting position; and
a control device configured to control the nozzle lifting and lowering mechanism, the XY movement mechanism, and the board conveyance device so that the component picked up by the nozzle is mounted on the board carried into the board mounting position, wherein
the control device includes
a component mounting position setting section configured to set, for each component to be mounted on the board, a component mounting position which is a position in the X direction and the Y direction at which the component is to be mounted,
a component mounting height setting section configured to set, for each component to be mounted on the board, a component mounting height which is a position in the Z direction at which the component is to be mounted,
a mounting position correction section configured to correct, for each component to be mounted on the board, the component mounting position of the component set by the component mounting position setting section with a first correction value that varies according to the component mounting height of the component set by the component mounting height setting section, and
an XY movement mechanism drive section configured to drive the XY movement mechanism based on the component mounting position corrected by the mounting position correction section.

2. The component mounting machine according to claim 1, further comprising:
a part camera configured to capture an image of the component picked up by the nozzle from below, wherein
the control device further includes a positional deviation calculation section configured to calculate a positional deviation of a center of the component with respect to a center of the nozzle based on the image captured by the part camera, and
the mounting position correction section further corrects the component mounting position corrected with the first correction value by using a second correction value for correcting the positional deviation calculated by the positional deviation calculation section.

3. A method for calculating a correction value, the method comprising:
a first mounting step of mounting a measurement component picked up by a nozzle at a component mounting target position which is a target position in an X direction and a Y direction set on a board mounting surface of a board positioned at a component mounting position of a component mounting machine in a state where a height of the board mounting surface is a first height;
a first deviation acquisition step of acquiring a first deviation which is a deviation between an actual mounting position of the measurement component and the component mounting target position by performing the first mounting step multiple times;
a second mounting step of mounting the measurement component picked up by the nozzle at the component mounting target position in a state where the height of the board mounting surface of the board positioned at the component mounting position of the component mounting machine is a second height different from the first height;
a second deviation acquisition step of acquiring a second deviation which is a deviation between an actual mounting position of the measurement component and the component mounting target position by performing the second mounting step multiple times; and
a correction value calculation step of calculating the correction value for correcting the component mounting target position for each height of the board mounting surface of the board by using the first deviation and the second deviation.

4. The calculating method according to claim 3, wherein
the first height is a height of the board mounting surface when the board is positioned at a reference height, and
the second height is lower than the first height.

5. The calculating method according to claim 3, wherein
the measurement component has a higher dimensional accuracy than a mass-produced component.
